(19) United States
(12) Patent Application Publication
(10) Pub. No.: US 2009/0101944 A1
(43) Pub. Date: Apr. 23, 2009

(54) ELECTRONIC DEVICE AND METHOD FOR MANUFACTURING THE SAME

(76) Inventor: Isao TAKASU, Kawasaki-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/026,193

(22) Filed: Feb. 5, 2008

(30) Foreign Application Priority Data
Feb. 6, 2007 (JP) 2007-26988

(51) Int. Cl. H01L 29/78; H01L 21/02; B41F 31/00

(52) U.S. Cl. 257/288; 438/197; 101/491; 257/E21.002; 257/E29.255

(57) ABSTRACT

It is made possible to form an interelectrode gap with high precision, without a decrease in the simplicity and convenience of the process to be carried out by an ink jet technique. A method for manufacturing an electronic device, includes: applying a water repellent agent onto a substrate by an ink jet technique to form a water repellent region on the substrate; dropping a solution containing a conductive ink material along edges of the water repellent region on the substrate by the ink jet technique to form a source electrode and a drain electrode; and forming a semiconductor layer to cover the water repellent region, the source electrode, and the drain electrode.

### CROSS-REFERENCE TO RELATED APPLICATION

This application is based upon and claims the benefit of priority from prior Japanese Patent Application No. 2007-26988 filed on Feb. 6, 2007 in Japan, the entire contents of which are incorporated herein by reference.

### BACKGROUND OF THE INVENTION

1. Field of the Invention

The present invention relates to an electronic device and a method for manufacturing the electronic device.

2. Related Art

In recent years, attention has been paid to the method for manufacturing the wirings of electronic devices by ink jet printing techniques. Printed wirings have conventionally been manufactured by screen printing. However, unlike the conventional printing techniques, ink jet printing is plateless printing, and noncontact printing can be performed by ink jet techniques. Accordingly, on-demand printing can be performed on a three-dimensional surface having concave and convex portions. An example of an electronic device that can be formed through a printing process is a field effect transistor. Particularly, the procedures for forming the source and drain electrodes of a field effect transistor requires a microfabrication technique. In each field effect transistor, the region between the source and drain electrodes serves as the channel region. Therefore, to reduce the driving voltage and to achieve higher drivability with a high current, the distance between the source and the drain (the gate length) should preferably be short.

However, the patterning accuracy achieved by an ink jet technique is normally lower than the patterning accuracy achieved by a photolithography technique. Therefore, source and drain electrodes that are printed by ink jet techniques are often inadequate, due to the problems with the liquid dropping path and the low accuracy of the liquid dropping positions.

Due to the low-accuracy liquid dropping positions, the error caused by the low positional accuracy of one of the electrodes is added to the error caused by the low positional accuracy of the other one of the electrodes at the time of image formation. As a result, the channel widths between the source and drain electrodes vary widely. Accordingly, the transistor characteristics also vary widely, and short-circuiting might be caused between the electrodes.

Suggested methods for forming small gate lengths by ink jet techniques include the following first to third methods.

The first method is disclosed by H. Sirringhaus et al., in Science 290 (2000) 2123. By this method, a polyimide weir is formed on a glass substrate by a photolithography technique in advance. A conductive ink is then dropped onto the side faces of the weir by an ink jet technique, so as to form the source and drain electrodes.

The second method is disclosed by Wang, J. Z.; Zheng, Z. H.; Li, H. W.; Huck, and W. T. S.; and Sirringhaus, H., in Nature Materials, 3, 171 (2004). By this method, a SiO₂ weir is formed by performing fine-line patterning on a silicon substrate. After that, the surface of the weir is processed with the use of fluorinated silane coupling. A conductive ink is then dropped onto this weir by an ink jet technique, so as to form the source and drain electrodes that are separated from each other by the weir.

The third method is disclosed by C. W. Sele, T. von Werne, R. H. Friend, and H. Sirringhaus in Advanced Materials 17, (2005) 997. By this method, only one (the source electrode, for example) of the two electrodes is formed on the substrate in advance. Here, the surface of the one electrode (the source electrode, for example) is coated with a water-repellent insulating material. A conductive ink is then dropped onto the coated electrode (the source electrode, for example), so as to form the other electrode (the drain electrode, for example). The ink droplets drip along a side face of the already formed electrode, and reach the surface of the substrate. Thus, the other electrode (the drain electrode, for example) is formed.

Each of the first and second methods utilizes the gap region between the source and drain electrodes patterned by a conventional semiconductor process, but hardly takes advantage of the simplicity and convenience of the process to be carried out by an ink jet technique. By the third method, the gate length is equivalent to the thickness of the coating layer on the surface of the electrode that is formed first. As a result, each field effect transistor formed by this method has a gate length smaller than 1 μm, and such a gate length limits the use of such field effect transistors.

### SUMMARY OF THE INVENTION

The present invention has been made in view of these circumstances, and an object thereof is to provide an electronic device and an electronic device manufacturing method by which an interelectrode gap can be formed with high precision, without a decrease in the simplicity and convenience of the process to be carried out by an ink jet technique.

An electronic device manufacturing method according to a first aspect of the present invention includes: applying a water repellent agent onto a substrate by an ink jet technique to form a water repellent region on the substrate; dropping a solution containing a conductive ink material along edges of the water repellent region on the substrate by the ink jet technique to form a source electrode and a drain electrode; and forming a semiconductor layer to cover the water repellent region, the source electrode, and the drain electrode.

An electronic device manufacturing method according to a second aspect of the present invention includes: forming a gate electrode on a substrate; forming a gate insulating film to cover the gate electrode; dropping a liquid containing a water repellent agent by the ink jet technique on the gate insulating film to form a water repellent region; dropping a solution containing a conductive ink material along the water repellent region on the gate insulating film by the ink jet technique to form a source electrode and a drain electrode; and forming a semiconductor layer to cover the water repellent region, the source electrode, and the drain electrode.

An electronic device according to a third aspect of the present invention includes: a substrate; a source electrode and a drain electrode that are formed at a distance from each other on the substrate; a water repellent region that is formed in a region on the substrate between the source electrode and the drain electrode and is formed with a water repellent agent having hydrolytic properties, end portions of the water repellent region being in contact with end portions of the source electrode and the drain electrode; a semiconductor layer that is formed to cover the source electrode, the drain electrode, and the water repellent region; a gate insulating film that is formed on the semiconductor layer; and a gate electrode that is formed on a portion of the gate insulating film, the portion being corresponding to a region between the source electrode and the drain electrode.

An electronic device according to a fourth aspect of the present invention includes: a substrate; a gate electrode that is formed on the substrate; a gate insulating film that is formed to cover the gate electrode; a source electrode and a drain electrode that are formed on the gate insulating film, a surface region of the gate insulating film located above the gate electrode being interposed between the source electrode and the drain electrode; a water repellent region that is formed on the gate insulating film between the source electrode and the drain electrode, and is formed with a water repellent agent having hydrolytic properties, end portions of the water repellent region being in contact with end portions of the source electrode and the drain electrode; and a semiconductor layer that is formed to cover the water repellent region, the source electrode, and the drain electrode.

### BRIEF DESCRIPTION OF THE DRAWINGS

FIGS. 1A to 1C are cross-sectional views illustrating a method for manufacturing an electronic device in accordance with a first embodiment;

FIGS. 2A to 2D are cross-sectional views illustrating the method for manufacturing the electronic device in accordance with the first embodiment;

FIG. 3 is a cross-sectional view of an electronic device manufactured by a manufacturing method in accordance with a second embodiment;

FIGS. 4A to 4F are cross-sectional views illustrating the method for manufacturing the electronic device in accordance with the second embodiment; and

FIGS. 5A to 5C illustrate the hydrolysis process carried out when a water repellent agent is applied onto the glass substrate.

### DESCRIPTION OF THE EMBODIMENTS

The following is a detailed description of embodiments of the present invention.

### First Embodiment

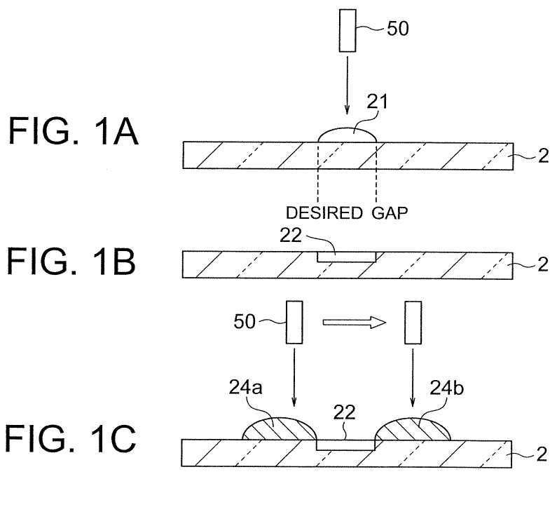

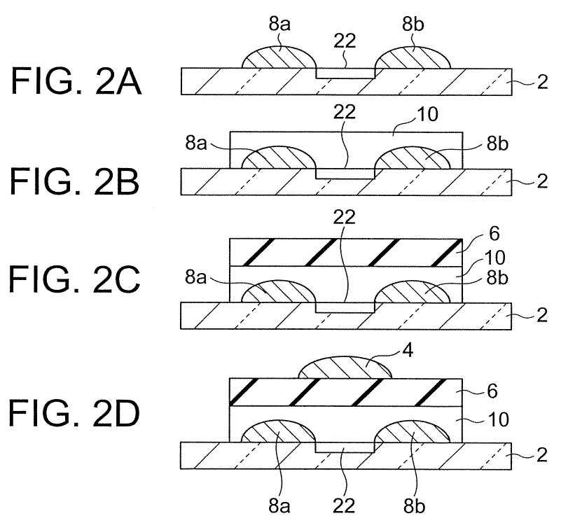

Referring to FIGS. 1A to 2D, a method for manufacturing an electronic device in accordance with a first embodiment of the present invention is described. The electronic device manufactured by the manufacturing method of this embodiment is a thin-film FET (Field Effect Transistor) of a top gate type. FIGS. 1A to 2D illustrate the procedures for manufacturing the electronic device.

First, a solution that is formed by dissolving a water repellent agent 21 with a solvent is applied onto the portion of a glass substrate 2 corresponding to the gap located between the source electrode and the drain electrode of the FET by an ink jet device 50 (see FIG. 1A). The solvent is removed to form a water repellent region 22 (see FIG. 1B). Alternatively, the water repellent agent may not be dissolved with a solvent, and may be dropped onto the substrate by an ink jet device. Also, the water repellent agent may be absorbed by a resin in a gel state, and the gel resin containing the water repellent agent may be applied onto the substrate by an ink jet device. In the case where the water repellent agent is absorbed by a resin in a gel state, the applied gel resin containing water repellent agent does not spread on the substrate, and the gap between the source electrode and the drain electrode can be maintained with high precision.

After that, the ink jet device 50 performs printing along edges of the water repellent region 22 on the glass substrate 2, using a solution formed by dissolving a water-repellent conductive ink with a solvent. In this manner, conductive ink regions 24a and 24b are formed (see FIG. 1C).

In the formation of the conductive ink regions, after forming the conductive ink region 24a, the ink jet device 50 moves to the location to form the conductive ink region 24b, as shown in FIG. 1C. As the ink having sufficient water repellency, a waterborne colloidal silver dispersion ink or an organic material ink such as waterborne PEDOT: PSS (polyethylene-dioxy-thiophene/polystyrene sulphonic acid) can be used.

The ink jet device mentioned in this specification may be a “piezo ink jet” device that discharges ink through the movement of a piezoelectric body caused by voltage application, a “thermal ink jet” device that discharges ink through air bubbles generated by heating the inside of the ink chamber, an “electrostatic ink jet” device that discharges ink using electrostatic force, or a “ultrasonic ink jet” device that discharges ink using ultrasonic force. To avoid adverse influence of heating, it is more preferable that a piezo ink jet device, an electrostatic ink jet device, or an ultrasonic ink jet device is used.

The solvent in the conductive ink regions 24a and 24b is then removed, so as to form a source electrode 8a and a drain electrode 8b, as shown in FIG. 2A. After that, a semiconductor layer 10 made of an organic material is formed so as to cover the source electrode 8a, the water repellent region 22, and the drain electrode 8b, as shown in FIG. 2B. Here, the semiconductor layer 10 is formed through solvent application performed by a vacuum vapor deposition technique, a spin coating technique, or an ink jet technique. Since this embodiment is based on a device manufacturing method according to an ink jet technique, it is preferable that the semiconductor layer 10 is formed by a coating technique using a solution, so as to increase the efficiency in the device manufacturing. The portion of the semiconductor layer 10 located on the water repellent region 22 serves as the channel.

A gate insulating film 6 is then formed on the semiconductor layer 10, as shown in FIG. 2C. A gate electrode 4 is then formed by a vapor deposition technique or a coating technique on the region of the gate insulating film 6 corresponding to the channel, as shown in FIG. 2D.

In the manufacturing method in accordance with this embodiment, the semiconductor layer 10 may be formed, while the water repellent region 22 maintains the water repellency. Also, the semiconductor layer 10 may be formed, after the water repellent agent is removed from the water repellent region 22 by a UV (ultraviolet) ozone process or a plasma process or the like. Further, the semiconductor layer 10 may be formed, after the water repellent agent is removed and processing is performed with another water repellent agent.

As described above, in accordance with this embodiment, a water repellent process is carried out by an ink jet device in advance, so as to form the water repellent region. The conductive ink regions to be the source electrode and the drain electrode are then formed by the ink jet device. Accordingly, the formed conductive ink regions cannot expand, and changes in the gap between the source electrode and the drain electrode due to the uneven spreading of the ink are prevented.

In a conventional case where a water repellent process is not carried out, the positional accuracy with respect to the channel is governed by the positional accuracy of the two-time printing with the electrode material. On the other hand, in a case where a water repellent region is formed in advance as in this embodiment, the positional accuracy with respect to the channel is governed by the positional accuracy of the one-time printing performed to form the water repellent region.

As described above, in accordance with this embodiment, the gap between the electrodes can be formed with high precision, without a decrease in the simplicity and convenience of the process carried out by the ink jet technique.

### Second Embodiment

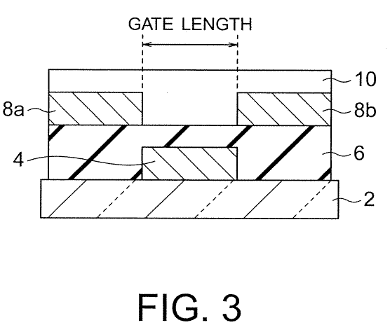

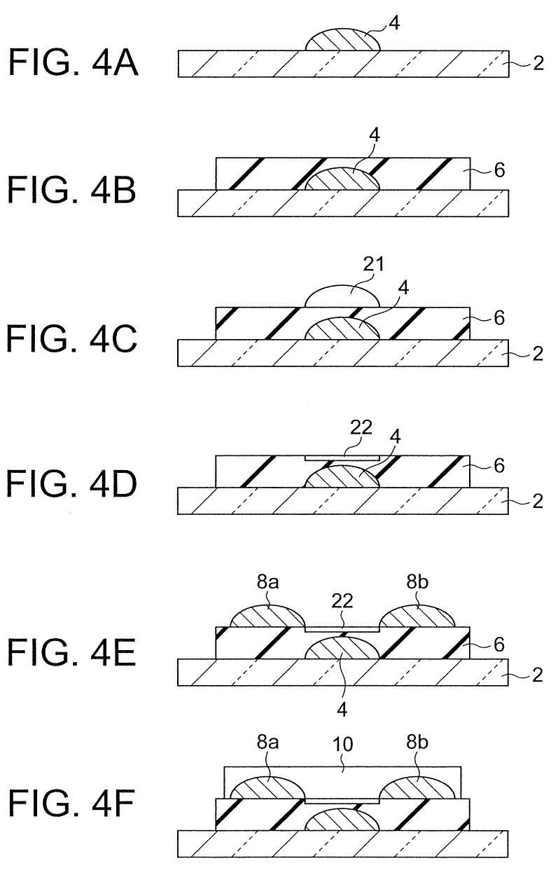

Referring now to FIGS. 3 to 4F, a method for manufacturing an electronic device in accordance with a second embodiment of the present invention is described. The electronic device to be manufactured by the manufacturing method in accordance with this embodiment is a thin-film FET of a bottom gate type, and FIG. 3 is a cross-sectional view of the thin-film FET. This electronic device has a gate electrode 4 formed on a glass substrate 2, and a gate insulating film 6 formed to cover the gate electrode 4 on the substrate 2. A source electrode 8a and a drain electrode 8b are formed on the gate insulating film 6, and the surface region of the gate insulating film 6 immediately above the gate electrode 4 is interposed between the source electrode 8a and the drain electrode 8b. A semiconductor layer 10 is also formed so as to cover the surface region of the gate insulating film 6 immediately above the gate electrode 4, the source electrode 8a, and the drain electrode 8b. The portion of the semiconductor layer located above the surface region of the gate insulating film 6 immediately above the gate electrode 4 serves as the channel.

Next, the manufacturing method in accordance with this embodiment is described.

First, printing is performed with a solution formed by dissolving a conductive ink with a solvent, so as to form a conductive ink region on the glass substrate 2. The solvent is then removed from the conductive ink region, so that the gate electrode 4 is formed, as shown in FIG. 4A. The gate insulating film 6 is then formed so as to cover the gate electrode 4, as shown in FIG. 4B.

A water repellent agent 21 is then applied onto the channel formation region of the gate insulating film 6 by an ink jet device (see FIG. 4C). In a case where only the water repellent agent is applied, the water repellent region 22 is formed in the channel formation region through this application procedure (see FIG. 4D). In a case where a solution formed by dissolving the water repellent agent 21 with a solvent or a resin containing the water repellent agent 21 is applied onto the channel formation region, the water repellent region 22 is formed in the channel formation region by drying the solvent or removing the resin through washing (see FIG. 4D).

Using the ink jet device, printing with a solution formed by dissolving a conductive ink with a solvent is performed along edges of the water repellent region 22. The solvent is then removed, so as to form the source electrode 8a and the drain electrode 8b (see FIG. 4E). After that, the semiconductor layer 10 is formed so as to cover the source electrode 8a and the drain electrode 8b. Thus, the FET is completed (see FIG. 4F).

As described above, in accordance with this embodiment, water repellent process is carried out by an ink jet device in advance, so as to form the water repellent region. The conductive ink regions to be the source electrode and the drain electrode are then formed by the ink jet device. Accordingly, the formed conductive ink regions cannot expand, and changes in the gap between the source electrode and the drain electrode due to the uneven spreading of the ink are prevented.

In a conventional case where a water repellent process is not carried out, the positional accuracy with respect to the channel is governed by the positional accuracy of the two-time printing with the electrode material. On the other hand, in a case where a water repellent region is formed in advance as in this embodiment, the positional accuracy with respect to the channel is governed by the positional accuracy of the one-time printing performed to form the water repellent region.

As described above, in accordance with this embodiment, the gap between the electrodes can be formed with high precision, without a decrease in the simplicity and convenience of the process carried out by the ink jet technique.

### Third Embodiment

Next, a method for manufacturing an electronic device in accordance with a third embodiment of the present invention is described.

The manufacturing method in accordance with this embodiment is the same as the manufacturing method in accordance with the first or second embodiment, except that a water repellent agent having hydrolytic properties is used and a waterborne ink is used as the conductive ink.

In a case where a water repellent agent having hydrolytic properties is used, and printing with a waterborne ink is performed on the end portions subjected to water-repellent processing, the water repellent portion is gradually hydrolyzed, starting from its end portions. As a result, the water repellency is lost, and the width of the water repellent portion becomes smaller. Accordingly, the end portions of the conductive ink region are in contact with the end portions of the water repellent region that have lost the water repellency. Thus, a FET having a smaller gate length can be manufactured by the manufacturing method in accordance with this embodiment, compared with a FET manufactured by the manufacturing method in accordance with a first or second embodiment. As the water repellent agent having hydrolytic properties, a silane agent can be used.

The water repellent effect of a silane coupling agent depends on the hydrocarbon backbone in the molecules. A hydrolytic reaction with a silane coupling agent occurs where there is a structure of Si—Cl or Si—O—X (here, X represents a hydrocarbon backbone such as CH₃ or CH₂CH₃), but a hydrolytic reaction does not occur where there is a structure of Si—X (here, X represents a hydrocarbon backbone such as CH₃ or CH₂CH₃). A hydrolytic reaction occurs where there is moisture, and the reaction is larger if the moisture has acidic properties or basicity.

PEDOT:PSS, which is the most widely used organic conductive ink, has acidic properties, and accordingly, is considered to be an electrode material that can readily cause a hydrolytic reaction.

Among silane agents, chlorosilane has high reactivity to moisture, and is not suitable for a process involving ink jet printing. Therefore, an alkoxysilane material that has low reactivity is suitable. Examples of alkoxysilane materials include the following materials, with Me representing a methyl group and Et represents an ethyl group: Si(OMe)₄, MeSi(OMe)₃, Me₂Si(OMe)₂, Me₃SiMe, C₂H₅Si(OMe)₃, n-C₃H₇Si(OMe)₃, n-C₆H₁₃Si(OMe)₃, n-C₁₀H₂₁Si(OMe)₃, CH═CHSi(OMe)₃, C₆H₅Si(OMe)₃, (C₆H₅)₂Si(OMe)₂, Si(OMe)₄, MeSi(OEt)₃, Me₂Si(OEt)₂, and Me₃SiOEt.

In a printing process, however, it is difficult to use a material having a low boiling point. Therefore, among the above described materials, those having boiling points at 100° C. or higher are suitable for printing. Such materials are: Si(OMe)₄, MeSi(OMe)₃, C₂H₅Si(OMe)₃, n-C₃H₇Si(OMe)₃, n-C₆H₁₃Si(OMe)₃, n-C₁₀H₂₁Si(OMe)₃, CH═CHSi(OMe)₃, C₆H₅Si(OMe)₃, (C₆H₅)₂Si(OMe)₂, Si(OMe)₄, MeSi(OEt)₃, and Me₂Si(OEt)₂.

In a case where an alkoxysilane material is used as the water repellent agent and a thin-film FET is manufactured by the manufacturing method in accordance with the first or second embodiment, the alkoxysilane material layer remains in the region (the water repellent region 22) between the source electrode 8a and the drain electrode 8b of the thin-film FET, unless the alkoxysilane material is removed.

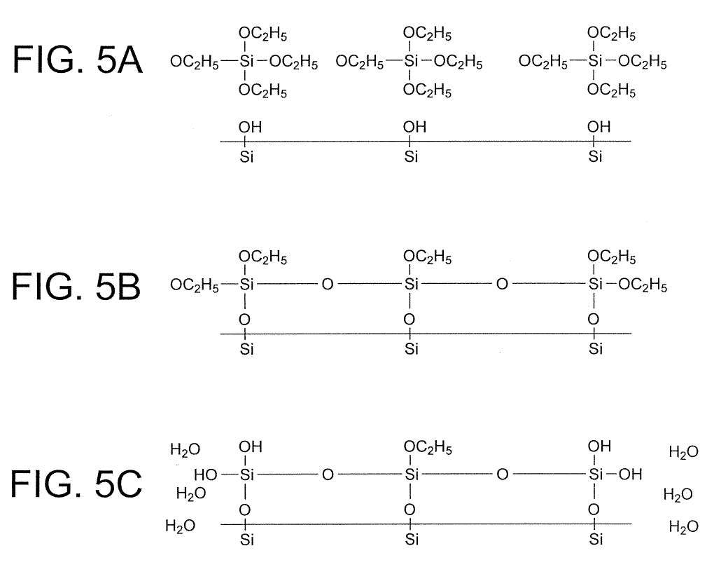

FIGS. 5A to 5C illustrate the hydrolysis process to be observed when the water repellent agent is applied onto the glass substrate.

First, printing is performed with tetraethoxysilane on the glass substrate, as shown in FIG. 5A. The hydroxyl group on the glass substrate then reacts with the tetraethoxysilane, to form a bond as shown in FIG. 5B. After that, a waterborne conductive ink is supplied to the end portions of the water repellent region formed with the tetraethoxysilane, as shown in FIG. 5C. As a result, the tetraethoxysilane at the end portions goes through hydrolysis, and becomes hydrophilic.

Through this process, part of the conductive ink eats away the water repellent region. Accordingly, a smaller channel length can be achieved. The formation of a gate length by this method can be controlled by adjusting the acid level of the conductive ink and the hydrolytic reaction time.

The conductive ink to be used in this process is preferably a waterborne silver nanocolloidal ink or waterborne PEDOT: PSS. Particularly, PEDET:PSS can cause a larger hydrolytic reaction, having acidic properties.

As described above, in accordance with this embodiment, the gap between the electrodes can be formed with high precision, without a decrease in the simplicity and convenience of the process carried out by the ink jet technique.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concepts as defined by the appended claims and their equivalents.

What is claimed is:

1. A method for manufacturing an electronic device, comprising:
applying a water repellent agent onto a substrate by an ink jet technique to form a water repellent region on the substrate;
dropping a solution containing a conductive ink material along edges of the water repellent region on the substrate by the ink jet technique to form a source electrode and a drain electrode; and
forming a semiconductor layer to cover the water repellent region, the source electrode, and the drain electrode.

2. The method according to claim 1, wherein the water repellent agent has hydrolytic properties.

3. The method according to claim 2, wherein:
the conductive ink material is a waterborne ink; and
a hydrolytic reaction is caused by the conductive ink material on end portions of the water repellent region.

4. The method according to claim 1, further comprising:
forming a gate insulating film on the semiconductor layer; and
forming a gate electrode in a region on the gate insulating film, the region being corresponding to a region between the source electrode and the drain electrode.

5. A method for manufacturing an electronic device, comprising:
forming a gate electrode on a substrate;
forming a gate insulating film to cover the gate electrode;
dropping a liquid containing a water repellent agent by the ink jet technique on the gate insulating film to form a water repellent region;
dropping a solution containing a conductive ink material along the water repellent region on the gate insulating film by the ink jet technique to form a source electrode and a drain electrode; and
forming a semiconductor layer to cover the water repellent region, the source electrode, and the drain electrode.

6. The method according to claim 5, wherein the water repellent agent has hydrolytic properties.

7. The method according to claim 6, wherein:
the conductive ink material is a waterborne ink; and
a hydrolytic reaction is caused by the conductive ink material on end portions of the water repellent region.

8. An electronic device comprising:
a substrate;
a source electrode and a drain electrode that are formed at a distance from each other on the substrate;
a water repellent region that is formed in a region on the substrate between the source electrode and the drain electrode and is formed with a water repellent agent having hydrolytic properties, end portions of the water repellent region being in contact with end portions of the source electrode and the drain electrode;
a semiconductor layer that is formed to cover the source electrode, the drain electrode, and the water repellent region;
a gate insulating film that is formed on the semiconductor layer; and
a gate electrode that is formed on a portion of the gate insulating film, the portion being corresponding to a region between the source electrode and the drain electrode.

9. The device according to claim 8, wherein the water repellent region includes an alkoxysilane material layer.

10. An electronic device comprising:
a substrate;
a gate electrode that is formed on the substrate;
a gate insulating film that is formed to cover the gate electrode;
a source electrode and a drain electrode that are formed on the gate insulating film, a surface region of the gate insulating film located above the gate electrode being interposed between the source electrode and the drain electrode;
a water repellent region that is formed on the gate insulating film between the source electrode and the drain electrode, and is formed with a water repellent agent having hydrolytic properties, end portions of the water repellent region being in contact with end portions of the source electrode and the drain electrode; and
a semiconductor layer that is formed to cover the water repellent region, the source electrode, and the drain electrode.

11. The device according to claim 10, wherein the water repellent region includes an alkoxysilane material layer.
